(19) United States
(12) Patent Application Publication
(10) Pub. No.: US 2026/0146808 A1
(43) Pub. Date: May 28, 2026

(54) COOLING DEVICE AND COOLING UNIT

(71) Applicant: NIDEC CORPORATION, Kyoto (JP)

(72) Inventors: Takaya OKUNO, Kyoto (JP); Yifan XING, Kyoto (JP)

(21) Appl. No.: 19/391,073

(22) Filed: Nov. 17, 2025

(30) Foreign Application Priority Data
Nov. 22, 2024 (JP) 2024-204048

(51) Int. Cl. F28F 9/02; F28F 3/12

(52) U.S. Cl. CPC F28F 9/0246; F28F 3/12; F28F 2210/00

(57) ABSTRACT

A cooling device includes a cover, first and second elbows, and first and second flow path pipes. The cover includes first and second openings through which a coolant circulates in a first surface. The first and second elbows are on the first surface and connected to the first and second openings. The first and second flow path pipe are on the first surface and connected to the first and second elbows. When viewed from a direction orthogonal or substantially orthogonal to the first surface, the first flow path pipe linearly extends in a direction inclined with respect to a flow path direction of the second elbow at a position adjacent to the second elbow, or the second flow path pipe is bent in a direction away from the first elbow at a position adjacent to the first elbow.

### CROSS-REFERENCE TO RELATED APPLICATIONS

The present application claims priority under 35 U.S.C. § 119 to Japanese Patent Application No. 2024-204048, filed on Nov. 22, 2024, the entire contents of which are hereby incorporated herein by reference.

### 1. Field of the Invention

The present disclosure relates to cooling devices and cooling units.

### 2. Background

A cooling device is known that cools a heat source using a coolant flowing through an internal flow path. A cooling unit in which a plurality of cooling devices are connected by flow path pipes is disclosed as a known technique.

In the cooling device, for example, constraints imposed by an installation location thereof may limit a location where a flow path pipe is introduced into the cooling device from outside or a location where the flow path pipe is led out from the cooling device to the outside. In the cooling device, it may be desirable to cause a coolant to flow in from a location where a temperature of generated heat is high. Furthermore, from the viewpoint of piping workability, it may also be desirable to allow flexibility in routing of the flow path pipe. Due to these circumstances, the routing of the flow path pipe for the cooling device may become complicated.

As the routing of the flow path pipe for the cooling device becomes complicated, an elbow that changes a direction of coolant flow and the flow path pipe may be arranged close to each other. For example, a flow path pipe that supplies the coolant from the outside to the cooling device may be arranged close to an elbow provided in a flow path pipe that sends the coolant discharged from the cooling device to the outside.

In a manufacturing process, the elbow is joined to the cooling device through heat treatment such as brazing. However, in a case where the flow path pipe is arranged close to the elbow, the flow path pipe may be deformed by heat when joining the elbow to the cooling device.

### SUMMARY

A cooling device according to an example embodiment of the present disclosure includes a cover, a first elbow, a second elbow, a first flow path pipe, and a second flow path pipe. The cover includes a first opening and a second opening through which a coolant circulates in a first surface. The first elbow is located on the first surface and connected to the first opening. The second elbow is located on the first surface and connected to the second opening. The first flow path pipe is located on the first surface and connected to the first elbow. The second flow path pipe is located on the first surface and connected to the second elbow. When viewed from a direction orthogonal or substantially orthogonal to the first surface, the first flow path pipe linearly extends in a direction inclined with respect to a flow path direction of the second elbow at a position adjacent to the second elbow, or the second flow path pipe is bent in a direction away from the first elbow at a position adjacent to the first elbow.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic plan view of a cooling device according to an example embodiment of the present disclosure.

FIG. 2 is an enlarged plan view illustrating a distance between a second elbow and a first flow path pipe according to the example embodiment.

FIG. 3 is a schematic perspective view of a cooling unit according to the example embodiment.

### DETAILED DESCRIPTION

Hereinafter, examples of cooling devices and cooling systems according to example embodiments of the present disclosure (hereinafter, referred to as “example embodiments”) will be described in detail with reference to the drawings. Note that the present disclosure is not limited by the example embodiments. In addition, the example embodiments can be combined as appropriate provided that processing content is not contradictory. In the following example embodiments, the same components are denoted by the same reference signs, and redundant description is omitted.

In each of the drawings referred to below, an orthogonal coordinate system is illustrated in which an X-axis direction, a Y-axis direction, and a Z-axis direction that are orthogonal to each other are defined, and the Z-axis direction is a vertically upward direction for ease of understanding. Further, a negative Y-axis direction side may be referred to as one side in a first direction, and a positive Y-axis direction side may be referred to as the other side in the first direction. A negative X-axis direction side may be referred to as one side in a second direction, and a positive X-axis direction side may be referred to as the other side in the second direction.

### Example Embodiment

### Configuration of Cooling Device

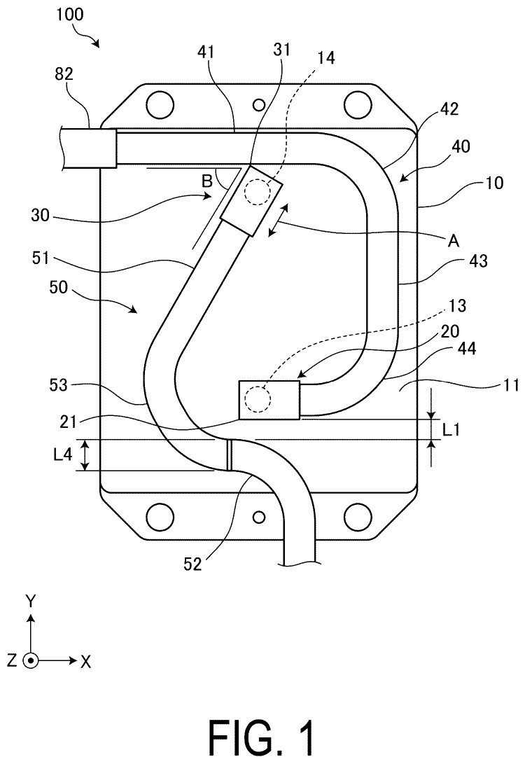

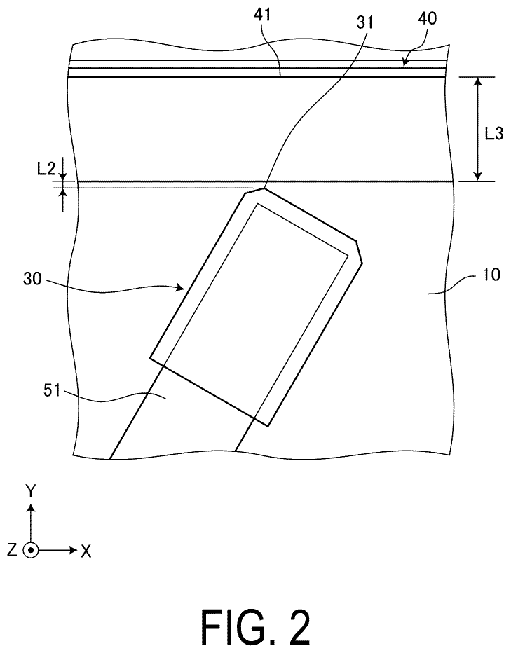

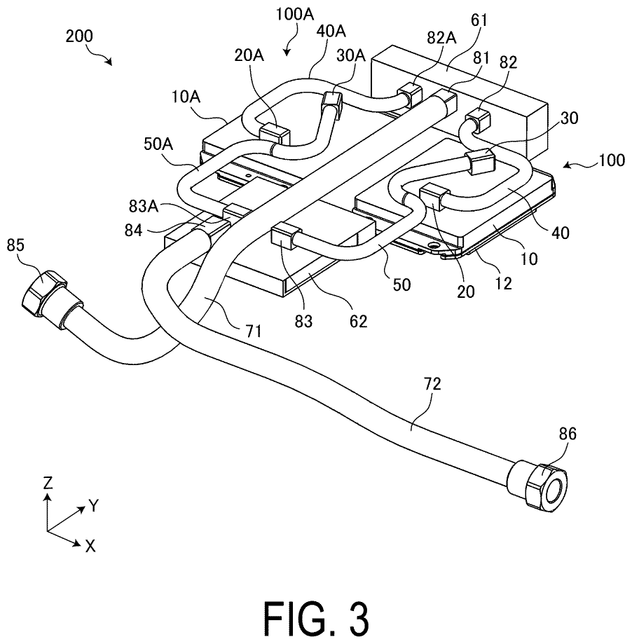

First, a configuration of a cooling device 100 according to an example embodiment will be described with reference to FIGS. 1 to 3. FIG. 1 is a schematic plan view of the cooling device 100 according to the example embodiment. FIG. 2 is an enlarged plan view indicating a distance between a second elbow 30 and a first flow path pipe 40 according to the example embodiment. FIG. 3 is a schematic perspective view of a cooling unit 200 according to the example embodiment.

As illustrated in FIG. 1, the cooling device 100 includes a cover 10, a first elbow 20, the second elbow 30, the first flow path pipe 40, and a second flow path pipe 50.

The cover 10 forms an internal space through which a coolant can circulate. The coolant is, for example, a cooling liquid. For example, an antifreeze liquid such as an ethylene glycol aqueous solution or a propylene glycol aqueous solution, or pure water is used as the cooling liquid.

The cover 10 has a first surface 11 and a second surface 12 (see FIG. 3) located opposite to the first surface 11. The first surface 11 and the second surface 12 may have a rectangular or substantially rectangular shape in a plan view. In an example illustrated in FIG. 1, long sides of the first surface 11 and the second surface 12 extend along the Y-axis direction, and short sides thereof extend along the X-axis direction. The first surface 11 and the second surface 12 may each be, for example, a flat surface. A first opening 13 and a second opening 14 through which the coolant circulates are located in the first surface 11. For example, the first opening 13 is an inlet through which the coolant flows into the cover 10, and the second opening 14 is an outlet through which the coolant flows out of the cover 10. In this case, the coolant flows inside the cover 10 from the first flow path pipe 40 through the first opening 13, circulates inside the cover 10, and then flows out to the second flow path pipe 50 through the second opening 14.

The cover 10 may be in contact with a heat generating component on the second surface 12. In this case, the heat generated in the heat generating component is transferred to the coolant via the second surface 12. The cover 10 may be formed of a material having relatively high thermal conductivity, such as copper or chromium copper. By forming the cover 10 using such a high thermal conductivity material, the heat of the heat generating component can be efficiently transferred to the coolant.

The first elbow 20 is located on the first surface 11 and connected to the first opening 13. The first elbow 20 changes a flow path direction of the coolant circulating inside the first elbow 20. To be specific, the first elbow 20 changes the flow path direction (XY-plane direction) of the coolant circulating from the first flow path pipe 40 to a direction toward the inside of the cover 10, specifically, a direction toward the first opening 13 (negative Z-axis direction). The first elbow 20 is formed to have, for example, a cuboid shape, and has a rectangular or substantially rectangular shape when viewed from a direction (Z-axis direction) orthogonal to the first surface 11. The first elbow 20 has a first corner 21 located adjacent to the second flow path pipe 50. The first corner 21 is a portion of the first elbow 20 located closest to the second flow path pipe 50. In other words, portions of the first elbow 20 other than the first corner 21 are located farther from the second flow path pipe 50 than the first corner 21.

The second elbow 30 is located on the first surface 11 and connected to the second opening 14. The second elbow 30 changes the flow path direction of the coolant circulating inside the second elbow 30. Specifically, the second elbow 30 changes the flow path direction (positive Z-axis direction) of the coolant flowing out from an internal space of the cover 10 through the second opening 14 to the flow path direction of the second flow path pipe 50 (XY-plane direction). The second elbow 30 is formed to have, for example, a cuboid shape, and has a rectangular or substantially rectangular shape when viewed from the direction orthogonal or substantially orthogonal to the first surface 11. The second elbow 30 has a second corner 31 located adjacent to the first flow path pipe 40. The second corner 31 is a portion of the second elbow 30 located closest to the first flow path pipe 40. In other words, portions of the second elbow 30 other than the second corner 31 are located farther from the first flow path pipe 40 than the second corner 31.

The first elbow 20 and the second elbow 30 may be formed using, for example, stainless steel or chromium copper.

The first flow path pipe 40 connects, for example, a second coupling 82 and the first elbow 20. The first flow path pipe 40 is formed using, for example, copper. The first flow path pipe 40 is located on the first surface 11 and connected to the first elbow 20. When viewed from the direction orthogonal or substantially orthogonal to the first surface 11, the first flow path pipe 40 includes a first linear portion 41 linearly extending in a direction inclined with respect to a flow path direction A of the second elbow 30 at a position adjacent to the second elbow 30. In other words, the flow path direction A of the second elbow 30, that is, an extending direction of the second elbow 30 is inclined with respect to an extending direction of the first linear portion 41 of the first flow path pipe 40. An angle B formed by the first linear portion 41 of the first flow path pipe 40 and the flow path direction A of the second elbow 30 may be an acute angle of, for example, about 15 degrees or more.

Specifically, the first flow path pipe 40 includes the first linear portion 41, a third bent portion 42, a second linear portion 43, and a fourth bent portion 44. The first linear portion 41 extends in the second direction (X-axis direction) orthogonal to the first direction (Y-axis direction) at the other side in the first direction (positive Y-axis direction side) of the first surface 11. The third bent portion 42 is connected to the first linear portion 41 at the other side in the second direction (positive X-axis direction side), and is bent to the one side in the first direction (negative Y-axis direction side). The second linear portion 43 is connected to the third bent portion 42 at the one side in the first direction (negative Y-axis direction side) and extends linearly to the one side in the first direction (negative Y-axis direction side). The fourth bent portion 44 is connected to the second linear portion 43 at the one side in the first direction (negative Y-axis direction side), and is bent to the one side in the second direction (negative X-axis direction side).

The second flow path pipe 50 is located on the first surface 11 and connects the second elbow 30 and a third elbow 83 (see FIG. 3). The second flow path pipe 50 is formed using, for example, copper. The second flow path pipe 50 includes a second bent portion 53 bent in a direction away from the first elbow 20 at a position adjacent to the first elbow 20.

Specifically, the second flow path pipe 50 includes a third linear portion 51 linearly extending from a position adjacent to the first linear portion 41 of the first flow path pipe 40 toward the one side in the first direction (negative Y-axis direction side) and the one side in the second direction (negative X-axis direction side). In other words, “extending toward the one side in the first direction and the one side in the second direction” means “extending obliquely with respect to the long side and the short side of the first surface 11”.

The second flow path pipe 50 further includes a first bent portion 52 and the second bent portion 53. The first bent portion 52 is bent in a direction away from the first elbow 20 at a position adjacent to the first elbow 20. Specifically, the first bent portion 52 extends from a position adjacent to the first corner 21 of the first elbow 20 toward the one side in the first direction (negative Y-axis direction side) and the other side in the second direction (positive X-axis direction side) in a curved shape bulging inward when viewed from the first elbow 20.

The second bent portion 53 is connected to the third linear portion 51 at the one side in the first direction (negative Y-axis direction side), and has a bent shape that approaches the first elbow 20 toward the other side in the second direction (positive X-axis direction side) while going around the first elbow 20. Specifically, the second bent portion 53 extends from an end portion of the third linear portion 51 located at the other side in the first direction (positive Y-axis direction side) and the one side in the second direction (negative X-axis direction side) with respect to first elbow 20 toward an end portion of the first bent portion 52 located at the one side in the first direction (negative Y-axis direction side) and the one side in the second direction (negative X-axis direction side) with respect to the first elbow 20 in a curved shape bulging outward as viewed from the first elbow 20. The second bent portion 53 is continuous with the first bent portion 52 at a position adjacent to the first elbow 20.

With the above configuration, a pipe configuration is obtained in which the coolant flows into the cover 10 from the one side in the first direction (negative Y-axis direction side) with respect to the cover 10 while the coolant is introduced from the other side in the first direction (positive Y-axis direction) and from the one side in the second direction (negative X-axis direction side) with respect to the cover 10. This makes it possible to improve piping workability of the flow path pipes in the case where a region of the internal space of the cover 10 at the one side in the first direction (negative Y-axis direction side) is preferably cooled more than a region thereof at the other side in the first direction (positive Y-axis direction side).

With the above configuration, it is possible to improve piping workability of the flow path pipes when the coolant is preferably discharged to the other side in the second direction (positive X-axis direction side).

The first flow path pipe 40 and the second flow path pipe 50 may have the bent portions described above, specifically, the first bent portion 52, the second bent portion 53, the third bent portion 42, and the fourth bent portion 44 at the positions overlapping the cover 10 when viewed from the direction orthogonal or substantially orthogonal to the first surface 11.

This makes it easy to achieve piping that bends away from the elbow, piping that extends linearly at an angle with respect to the flow path direction of the elbow, and the like. Even when there are constraints on piping to the outside of the cooling device 100, the piping is easily arranged. In addition, the degree of freedom in designing the outside of the cooling device 100 can be enhanced.

As described above, the second flow path pipe 50 includes the first bent portion 52 and the second bent portion 53. The first bent portion 52 is bent in the direction away from the first elbow 20 at the position adjacent to the first elbow 20. The second bent portion 53 has a bent shape that approaches the first elbow 20 while going around the first elbow 20, and is continuous with the first bent portion 52 at a position adjacent to the first elbow 20.

The second flow path pipe 50 can easily avoid the elbow. Since the first bent portion 52 and the second bent portion 53 provide the flow path pipe with flexibility, piping workability of the flow path pipe can be improved.

In the present example embodiment, an example is described in which the second flow path pipe 50 includes a plurality of the bent portions, but the present disclosure is not limited thereto, and the first flow path pipe 40 may include the plurality of bent portions. Both the first flow path pipe 40 and the second flow path pipe 50 may include the plurality of bent portions. That is, at least one of the first flow path pipe 40 or the second flow path pipe 50 preferably includes the plurality of bent portions.

This makes it easy to achieve piping that bends away from the elbow, piping that extends linearly at an angle with respect to the flow path direction of the elbow, and the like. Even when there are constraints on piping to the outside of the cooling device 100, the piping is easily arranged. In addition, the degree of freedom in designing the outside of the cooling device 100 can be enhanced.

A proximity distance between the first elbow 20 and the second flow path pipe 50 and a proximity distance between the second elbow 30 and the first flow path pipe 40 may be smaller than diameters of the first flow path pipe 40 and the second flow path pipe 50. Specifically, a distance L1 between the first elbow 20 and the second flow path pipe 50 at a position where the first elbow 20 and the second flow path pipe 50 are adjacent to each other may be smaller than a width L3 (see FIG. 2) of the first flow path pipe 40 and a width L4 of the second flow path pipe 50. A distance L2 (see FIG. 2) between the second elbow 30 and the first flow path pipe 40 at a position where the second elbow 30 and the first flow path pipe 40 are adjacent to each other may be smaller than the width L3 of the first flow path pipe 40 and the width L4 of the second flow path pipe 50.

In the above-described configuration, the closest distance between the first elbow 20 and the second flow path pipe 50 and the closest distance between the second elbow 30 and the first flow path pipe 40 are each smaller than the width L3 of the first flow path pipe 40 and the width L4 of the second flow path pipe 50. This makes it possible to enhance the degree of freedom in the arrangement of the first elbow 20 and the second elbow 30. In addition, the degree of freedom in designing the flow paths inside the cooling device 100 can be enhanced.

According to the cooling device 100 configured as described above, a range in which the first flow path pipe 40 and the second elbow 30 are adjacent to each other and a range in which the second flow path pipe 50 and the first elbow 20 are adjacent to each other can be reduced. For example, this makes it possible to suppress deformation of the second flow path pipe 50 close to the first elbow 20 and deformation of the first flow path pipe 40 close to the second elbow 30 due to heat when the first elbow 20 and the second elbow 30 are joined by brazing.

As described above, the first elbow 20 and the second elbow 30 have a rectangular or substantially rectangular shape when viewed from the direction orthogonal or substantially orthogonal to the first surface 11. In the cooling device 100, the first elbow 20 and the second flow path pipe 50 are not arranged in parallel, and the second elbow 30 and the first flow path pipe 40 are not arranged in parallel, and thus, the range in which the first elbow 20 and the second flow path pipe 50 are adjacent to each other and the range in which the second elbow 30 and the first flow path pipe 40 are adjacent to each other can be reduced. For example, this makes it possible to suppress deformation of the second flow path pipe 50 close to the first elbow 20 and deformation of the first flow path pipe 40 close to the second elbow 30 due to heat when the first elbow 20 and the second elbow 30 are joined by brazing.

As described above, among the first elbow 20, the first corner 21 is arranged closest to the second flow path pipe 50; and among the second elbow 30, the second corner 31 is arranged closest to the first flow path pipe 40. With the above-discussed arrangement, the range in which the first flow path pipe 40 and the second elbow 30 are adjacent to each other and the range in which the second flow path pipe 50 and the first elbow 20 are adjacent to each other can be reduced. For example, this makes it possible to suppress the deformation of the second flow path pipe 50 close to the first elbow 20 and the deformation of the first flow path pipe 40 close to the second elbow 30 due to heat when the first elbow 20 and the second elbow 30 are joined by brazing.

As described above, the angle B formed by the first linear portion 41 of the first flow path pipe 40 and the flow path direction A of the second elbow 30 is an acute angle of about 15 degrees or more. With this configuration, the range in which the first flow path pipe 40 and the second elbow 30 are adjacent to each other can be reduced. For example, this makes it possible to suppress the deformation of the first flow path pipe 40 close to the second elbow 30 due to the heat when the second elbow 30 is joined by brazing.

### Configuration of Cooling Unit

Next, a configuration example of the cooling unit 200 according to the example embodiment will be described with reference to FIG. 3. As illustrated in FIG. 3, the cooling unit 200 includes the cooling device 100 described above, a first manifold 61, a second manifold 62, a third flow path pipe 71, and a fourth flow path pipe 72.

The cooling unit 200 includes a plurality of the cooling devices 100. In the present example embodiment, the cooling unit 200 includes two cooling devices 100, but the number of cooling devices is not particularly limited, and three or more cooling devices 100 may be provided. Each of the plurality of cooling devices 100 is in contact with a heat generating component as a heat source, and absorbs heat from the heat generating component. In the cooling devices 100, the first flow path pipe 40 and the second flow path pipe 50 are symmetrically arranged in the second direction. For example, the cooling device 100 at the other side in the second direction (positive X-axis direction side) may be provided symmetrically in the second direction to a cooling device 100A at the one side in the second direction (negative X-axis direction side), and the other side in the second direction (positive X-axis direction side) of the third flow path pipe 71 may be located between the cooling device 100A and the cooling device 100 when viewed from the direction orthogonal or substantially orthogonal to the first surface 11. The first flow path pipe 40 and the second flow path pipe 50 of the cooling device 100 at the other side in the second direction (positive X-axis direction side) are symmetrical in the second direction to a first flow path pipe 40A and a second flow path pipe 50A of the cooling device 100A at the one side in the second direction (negative X-axis direction side).

This makes it possible to improve piping workability of the flow path pipes when a plurality of the heat sources are additionally provided.

The first manifold 61 connects, for example, a first coupling 81, the second coupling 82, and a second coupling 82A. As illustrated in FIG. 3, the first manifold 61 may be located at the other side in the first direction (positive Y-axis direction side) of the cooling device 100 and the cooling device 100A. With this configuration, the first manifold 61 is connected to the first coupling 81 at the one side in the first direction (negative Y-axis direction side). The first manifold 61 is connected at the one side in the first direction (negative Y-axis direction side) thereof to the second coupling 82 and the second coupling 82A at both sides of the first coupling 81 in the second direction (both sides in the X-axis direction). The first manifold 61 extends linearly in the second direction (X-axis direction) when viewed from the direction orthogonal or substantially orthogonal to the first surface 11.

Alternatively, the first manifold 61 may be located between the cooling device 100 and the cooling device 100A (not illustrated). With this configuration, the first manifold 61 is connected to the first coupling 81 at the one side in the first direction (negative Y-axis direction side). The first manifold 61 is connected to the second coupling 82 and the second coupling 82A at the other side in the first direction (positive Y-axis direction side). The first manifold 61 extends linearly in the first direction when viewed from the direction orthogonal or substantially orthogonal to the first surface 11.

The second manifold 62 connects, for example, the third elbow 83 and a third elbow 83A, and a fourth elbow 84. The second manifold 62 is located at the one side in the first direction (negative Y-axis direction side) of the cooling device 100 and the cooling device 100A. An upper face of the second manifold 62 is connected to the fourth elbow 84 at the one side in the first direction (negative Y-axis direction side). In the second manifold 62, the third elbow 83A is connected to the fourth elbow 84 at the other side in the first direction (positive Y-axis direction side), and the third elbow 83 is connected to the fourth elbow 84 on the upper face of the second manifold 62 at the other side in the first direction (positive Y-axis direction side) and the other side in the second direction (positive X-axis direction side).

The first manifold 61 and the second manifold 62 may be formed using, for example, copper or chromium copper.

The third flow path pipe 71 circulates, for example, the coolant sent from a pump (not illustrated) to the first manifold 61. The third flow path pipe 71 is connected to the first coupling 81 at the other side in the first direction (positive Y-axis direction side). The third flow path pipe 71 is connected to a third coupling 85 at the one side in the first direction (negative Y-axis direction side). An inner diameter of the third flow path pipe 71 may be larger than inner diameters of the first flow path pipe 40 and the second flow path pipe 50. An outer diameter of the third flow path pipe 71 may be larger than outer diameters of the first flow path pipe 40 and the second flow path pipe 50.

The fourth flow path pipe 72 circulates, for example, the coolant sent from the second manifold 62. The fourth flow path pipe 72 is connected to the fourth elbow 84 at the other side in the first direction (positive Y-axis direction side). The fourth flow path pipe 72 is connected to a fourth coupling 86 at the one side in the first direction (negative Y-axis direction side). An inner diameter of the fourth flow path pipe 72 may be larger than the inner diameters of the first flow path pipe 40 and the second flow path pipe 50. An outer diameter of the fourth flow path pipe 72 may be larger than the outer diameters of the first flow path pipe 40 and the second flow path pipe 50.

The third flow path pipe 71 and the fourth flow path pipe 72 may be formed using, for example, stainless steel.

The brazing process when manufacturing the cooling unit 200 is performed in three stages. A temperature setting of heating in each stage is such that the temperature is lowered in the order of a first stage, a second stage, and a third stage. This prevents wax of the previous stage from melting in the subsequent stage.

In the first stage, the third flow path pipe 71 and the first coupling 81 are brazed, and the fourth elbow 84 and the fourth flow path pipe 72 are brazed.

In the second stage, the first coupling 81 and the first manifold 61 are brazed, and the first manifold 61 and the second couplings 82 and 82A are brazed. In the second stage, the first elbow 20 and the cover 10 are brazed, a first elbow 20A and a cover 10A are brazed, the cover 10 and the second elbow 30 are brazed, and the cover 10A and a second elbow 30A are brazed. In the second stage, the third elbow 83 and third elbow 83A are brazed to the second manifold 62, and the second manifold 62 is brazed to the fourth elbow 84.

In the third stage, the third coupling 85 and the third flow path pipe 71 are brazed. In the third stage, the second coupling 82 and the first flow path pipe 40 are brazed, the second coupling 82A and the first flow path pipe 40A are brazed, the first flow path pipe 40 and the first elbow 20 are brazed, and the first flow path pipe 40A and the first elbow 20A are brazed. In the third stage, the second elbow 30 and the second flow path pipe 50 are brazed, the second elbow 30A and the second flow path pipe 50A are brazed, the second flow path pipe 50 and the third elbow 83 are brazed, and the second flow path pipe 50A and the third elbow 83A are brazed. In the third stage, the fourth flow path pipe 72 and the fourth coupling 86 are brazed.

Vacuum brazing, diffusion bonding, heating in a continuous furnace, heating with an IH heater, or the like can be used as a heating method in the brazing process.

The present technique can also have the following configurations.
(1)

A cooling device including a cover including a first opening and a second opening through which a coolant circulates in a first surface, a first elbow located on the first surface and connected to the first opening, a second elbow located on the first surface and connected to the second opening, a first flow path pipe located on the first surface and connected to the first elbow, and a second flow path pipe located on the first surface and connected to the second elbow, wherein as viewed from a direction orthogonal or substantially orthogonal to the first surface, the first flow path pipe linearly extends in a direction inclined with respect to a flow path direction of the second elbow at a position adjacent to the second elbow, or the second flow path pipe is bent in a direction away from the first elbow at a position adjacent to the first elbow.
(2)

The cooling device according to (1), wherein the first elbow and the second elbow each have a rectangular or substantially rectangular shape as viewed from the direction orthogonal or substantially orthogonal to the first surface.
(3)

The cooling device according to (1) or (2), wherein the first flow path pipe and the second flow path pipe each include a bent portion at a position overlapping the cover as viewed from the direction orthogonal or substantially orthogonal to the first surface.
(4)

The cooling device according to (3), wherein at least one of the first flow path pipe or the second flow path pipe includes a plurality of the bent portions.
(5)

The cooling device according to any one of (1) to (4), wherein the second flow path pipe includes a first bent portion that is bent in the direction away from the first elbow at the position adjacent to the first elbow, and a second bent portion that has a bent shape approaching the first elbow while going around the first elbow, and is continuous with the first bent portion at a position adjacent to the first elbow.
(6)

The cooling device according to any one of (1) to (5), wherein a distance between the first elbow and the second flow path pipe at a position where the first elbow and the second flow path pipe are adjacent to each other and a distance between the second elbow and the first flow path pipe at a position where the second elbow and the first flow path pipe are adjacent to each other are smaller than widths of the first flow path pipe and the second flow path pipe.
(7)

The cooling device according to any one of (2) to (6), wherein the first elbow includes a first corner located adjacent to the second flow path pipe, the second elbow includes a second corner located adjacent to the first flow path pipe, among the first elbow, the first corner is located closer to the second flow path pipe than remaining portions of the first elbow are, and the second corner is located closest to the first flow path pipe than remaining portions of the second elbow are.
(8)

The cooling device according to any one of (1) to (7), wherein an angle defined by a portion of the first flow path pipe extending linearly in the direction inclined with respect to the flow path direction of the second elbow at the position adjacent to the second elbow and the flow path direction of the second elbow is an acute angle of about 15 degrees or more.
(9)

The cooling device according to any one of (1) to (8), wherein the first flow path pipe includes at another side in a first direction of the first surface, a first linear portion extending in a second direction orthogonal or substantially orthogonal to the first direction, a third bent portion connected to the first linear portion at another side in the second direction and bent to one side in the first direction, a second linear portion connected to the third bent portion at the one side in the first direction and linearly extending to the one side in the first direction; and a fourth bent portion connected to the second linear portion at the one side in the first direction and bent to one side in the second direction, and the second flow path pipe includes a third linear portion linearly extending toward the one side in the first direction and the one side in the second direction from a position adjacent to the first linear portion.
(10)

The cooling device according to (9), wherein the second flow path pipe includes a first bent portion that is bent in the direction away from the first elbow at the position adjacent to the first elbow, and a second bent portion that is connected to the third linear portion at the one side in the first direction, has a bent shape approaching the first elbow toward the other side in the second direction while going around the first elbow, and is continuous with the first bent portion at a position adjacent to the first elbow.
(11)

A cooling unit including a plurality of the cooling devices according to any one of (1) to (10), wherein the first flow path pipe and the second flow path pipe in the cooling devices are symmetrically arranged in the second direction.

The example embodiments disclosed herein are to be considered in all respects as illustrative and not restrictive. In actuality, the above-described example embodiments may be embodied in a variety of forms. Furthermore, the above-described example embodiments may be omitted, replaced, or modified in various forms without departing from the scope and spirit of the appended claims.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device comprising:
a cover including a first opening and a second opening through which a coolant circulates in a first surface;
a first elbow located on the first surface and connected to the first opening;
a second elbow located on the first surface and connected to the second opening;
a first flow path pipe located on the first surface and connected to the first elbow; and
a second flow path pipe located on the first surface and connected to the second elbow; wherein
as viewed from a direction orthogonal or substantially orthogonal to the first surface, the first flow path pipe linearly extends in a direction inclined with respect to a flow path direction of the second elbow at a position adjacent to the second elbow, or the second flow path pipe is bent in a direction away from the first elbow at a position adjacent to the first elbow.

2. The cooling device according to claim 1, wherein the first elbow and the second elbow each have a rectangular or substantially rectangular shape as viewed from the direction orthogonal or substantially orthogonal to the first surface.

3. The cooling device according to claim 1, wherein the first flow path pipe and the second flow path pipe each include a bent portion at a position overlapping the cover as viewed from the direction orthogonal or substantially orthogonal to the first surface.

4. The cooling device according to claim 3, wherein at least one of the first flow path pipe or the second flow path pipe includes a plurality of the bent portions.

5. The cooling device according to claim 1, wherein the second flow path pipe includes:
a first bent portion that is bent in the direction away from the first elbow at the position adjacent to the first elbow; and
a second bent portion that has a bent shape approaching the first elbow while going around the first elbow, and that is continuous with the first bent portion at a position adjacent to the first elbow.

6. The cooling device according to claim 1, wherein a distance between the first elbow and the second flow path pipe at a position where the first elbow and the second flow path pipe are adjacent to each other and a distance between the second elbow and the first flow path pipe at a position where the second elbow and the first flow path pipe are adjacent to each other are smaller than widths of the first flow path pipe and the second flow path pipe.

7. The cooling device according to claim 2, wherein
the first elbow includes a first corner located adjacent to the second flow path pipe;
the second elbow includes a second corner located adjacent to the first flow path pipe;
the first corner is located closer to the second flow path pipe than remaining portions of the first elbow; and
the second corner is located closest to the first flow path pipe than remaining portions of the second elbow.

8. The cooling device according to claim 1, wherein an angle defined by a portion of the first flow path pipe extending linearly in the direction inclined with respect to the flow path direction of the second elbow at the position adjacent to the second elbow and the flow path direction of the second elbow is an acute angle of about 15 degrees or more.

9. The cooling device according to claim 1, wherein
the first flow path pipe includes:
at another side in a first direction of the first surface, a first linear portion extending in a second direction orthogonal or substantially orthogonal to the first direction;
a third bent portion connected to the first linear portion at another side in the second direction and bent to one side in the first direction;
a second linear portion connected to the third bent portion at the one side in the first direction and linearly extending to the one side in the first direction; and
a fourth bent portion connected to the second linear portion at the one side in the first direction and bent to one side in the second direction; and
the second flow path pipe includes a third linear portion linearly extending toward the one side in the first direction and the one side in the second direction from a position adjacent to the first linear portion.

10. The cooling device according to claim 9, wherein the second flow path pipe includes:
a first bent portion that is bent in the direction away from the first elbow at the position adjacent to the first elbow; and
a second bent portion that is connected to the third linear portion at the one side in the first direction, has a bent shape approaching the first elbow toward the other side in the second direction while going around the first elbow, and is continuous with the first bent portion at a position adjacent to the first elbow.

11. A cooling unit comprising:
a plurality of the cooling devices according to claim 9;
wherein
the first flow path pipe and the second flow path pipe in the cooling devices are symmetrically arranged in the second direction.
